(19) United States
(12) Patent Application Publication
(10) Pub. No.: US 2026/0013156 A1
(43) Pub. Date: Jan. 8, 2026

(54) NITRIDE SEMICONDUCTOR DEVICE AND PRODUCTION METHOD THEREFOR

(71) Applicants: TOYODA GOSEI CO., LTD., Kiyosu-shi (JP); PANASONIC HOLDINGS CORPORATION, Osaka (JP)

(72) Inventors: Kota YASUNISHI, Aichi (JP); Nariaki TANAKA, Aichi (JP); Junichi TAKINO, Osaka (JP); Tomoaki SUMI, Osaka (JP)

(21) Appl. No.: 19/256,970

(22) Filed: Jul. 1, 2025

(30) Foreign Application Priority Data
Jul. 3, 2024 (JP) 2024-107094

(51) Int. Cl. H10D 8/60; H10D 8/01; H10D 62/85

(52) U.S. Cl. CPC H10D 8/60; H10D 8/051; H10D 62/8503

(57) ABSTRACT

A nitride semiconductor device includes: a back surface electrode; a semiconductor substrate; a semiconductor layer, and a front surface element, stacked in this order, and in the semiconductor substrate, a concentration of a donor element is 1×10¹⁹ cm⁻³ or more in a depth range of at least 100 nm from a boundary surface between the semiconductor substrate and the back surface electrode.

### CROSS-REFERENCE TO RELATED APPLICATION

This application is based on and claims priority under 35 USC 119 from Japanese Patent Application No. 2024-107094 filed on Jul. 3, 2024.

### TECHNICAL FIELD

The present invention relates to a nitride semiconductor device and a production method therefor.

### BACKGROUND ART

In order to produce a nitride semiconductor device including a front surface element and a back surface electrode, it is common to form the back surface electrode after forming the front surface element. At this time, in order to reduce a contact resistance between a semiconductor substrate and the back surface electrode, a heat treatment is performed after the back surface electrode is formed to promote alloying at an interface between the semiconductor substrate and the back surface electrode. However, since the heat treatment temperature reaches 400° C. to 500° C., device properties of the front surface element may deteriorate. In addition, the heat treatment increases a production cost. Therefore, it is desired to reduce the contact resistance between the semiconductor substrate and the back surface electrode without performing a heat treatment.

Therefore, for example, Patent Literature 1 discloses the following method as a method of reducing the contact resistance between the semiconductor substrate and the back surface electrode by a low-temperature heat treatment. That is, a peak concentration of oxygen contained in an interface between a semiconductor substrate and a back surface electrode is increased by forming the back surface electrode after performing an oxygen plasma treatment on a back surface of the semiconductor substrate, and then a peak concentration of carbon is reduced, thereby enabling alloying at a low temperature in a subsequent heat treatment, and achieving a contact resistance of about 1×10⁻⁴ Ωcm² between the semiconductor substrate and the back surface electrode.

Patent Literature 1: JP2010−225767A

### SUMMARY OF INVENTION

However, although it is necessary to further reduce the contact resistance between the semiconductor substrate and the back surface electrode in order to meet a demand for increasing a current of the nitride semiconductor device, it is difficult to further reduce the contact resistance by the method disclosed in Patent Literature 1. Further, controllability of increasing the oxygen concentration by the oxygen plasma treatment is poor, and reproducibility thereof is also low. In addition, the oxygen plasma treatment may cause physical damage to the back surface of the semiconductor substrate to deteriorate the contact resistance. Further, when the back surface of the semiconductor substrate is cleaned after the oxygen plasma treatment, the oxygen concentration cannot be maintained at a high concentration, and therefore, in the case where an unintended contaminant or oxide is present on the back surface of the semiconductor substrate, the contact resistance deteriorates. Therefore, there is room for further improvement in the method disclosed in Patent Literature 1.

The present invention has been made in view of the above problems, and an object thereof is to provide a nitride semiconductor device capable of reducing a contact resistance between a semiconductor substrate and a back surface electrode without performing a high-temperature heat treatment to meet a demand for increasing a current.

An aspect of the present invention provides a nitride semiconductor device including: a back surface electrode; a semiconductor substrate; a semiconductor layer; and a front surface element stacked in this order, in which in the semiconductor substrate, a donor element concentration is 1×10¹⁹ cm⁻³ or more in a depth range of at least 100 nm from a boundary surface between the semiconductor substrate and the back surface electrode.

Another aspect of the present invention provides a method for producing a nitride semiconductor device in which a back surface electrode, a semiconductor substrate, a semiconductor layer, and a front surface element are stacked in this order, the method including: a semiconductor substrate formation step of crystal-growing the semiconductor substrate such that a donor element concentration is 1×10¹⁹ cm⁻³ or more in the semiconductor substrate in a depth range of at least 100 nm from a boundary surface between the semiconductor substrate and the back surface electrode; a semiconductor layer formation step of forming the semiconductor layer on one surface of the semiconductor substrate; a front surface element formation step of forming the front surface element on the semiconductor layer; an acid cleaning step of acid-cleaning a surface of the semiconductor substrate opposite to a side on which the semiconductor layer is formed; and a back surface electrode formation step of forming the back surface electrode on the surface of the semiconductor substrate opposite to the side on which the semiconductor layer is formed.

In the nitride semiconductor device according to the above aspect, since, in the semiconductor substrate, the donor element concentration in the depth range of at least 100 nm from the boundary surface between the semiconductor substrate and the back surface electrode is 1×10¹⁹ cm⁻³ or more, a region where the donor element concentration is a high concentration in the semiconductor substrate is present up to a sufficiently deep position from the boundary surface. Accordingly, an effect of reducing a contact resistance between the semiconductor substrate and the back surface electrode can be sufficiently obtained. As a result, a nitride semiconductor device having an increased current can be obtained without performing a high-temperature heat treatment.

In the method for producing a nitride semiconductor device according to the another aspect, the semiconductor substrate is crystal-grown such that the donor element concentration is 1×10¹⁹ cm⁻³ or more in the semiconductor substrate in the depth range of at least 100 nm from the boundary surface between the semiconductor substrate and the back surface electrode. Accordingly, since the region where the donor element concentration is a high concentration in the semiconductor substrate is present up to a sufficiently deep position from the boundary surface, the effect of reducing the contact resistance between the semiconductor substrate and the back surface electrode can be sufficiently obtained. As a result, a nitride semiconductor device having an increased current can be obtained without performing a high-temperature heat treatment.

As described above, according to the above aspects, it is possible to provide a nitride semiconductor device capable of reducing a contact resistance between a semiconductor substrate and a back surface electrode without performing a high-temperature heat treatment to meet a demand for increasing a current.

### BRIEF DESCRIPTION OF DRAWINGS

FIG. 1 is a conceptual diagram showing a configuration of a nitride semiconductor device according to a first embodiment.

FIG. 2 shows analysis results of element contents in a semiconductor substrate and a back surface electrode in the first embodiment.

FIG. 3 is a flowchart showing a method for producing a nitride semiconductor device according to the first embodiment.

### DESCRIPTION OF EMBODIMENTS

In the nitride semiconductor device, in the semiconductor substrate, the donor element concentration is preferably 1×10¹⁹ cm⁻³ or more and 1×10²² cm⁻³ or less in the depth range of at least 100 nm from the boundary surface between the semiconductor substrate and the back surface electrode. In the case where the donor element concentration in the semiconductor substrate in this range is more than 1×10²² cm⁻³, crystallinity of the semiconductor substrate may decrease, but by setting the donor element concentration in this range to 1×10²² cm⁻³ or less, the decrease in crystallinity of the semiconductor substrate can be prevented, which can contribute to improving a performance of the nitride semiconductor device.

In the nitride semiconductor device, a contact resistance between the semiconductor substrate and the back surface electrode is preferably 1×10⁻⁵ Ωcm² or less. In this case, since the contact resistance between the semiconductor substrate and the back surface electrode is sufficiently reduced, it is possible to meet a demand for increasing a current.

In the nitride semiconductor device, the contact resistance between the semiconductor substrate and the back surface electrode is preferably 2×10⁻⁶ Ωcm² or less. In this case, since the contact resistance between the semiconductor substrate and the back surface electrode is further sufficiently reduced, it is possible to meet the demand for increasing a current.

In the nitride semiconductor device, a donor element in the semiconductor substrate may be at least one of O, Si or Ge. In this case, the donor element concentration in the semiconductor substrate can be easily increased.

In the nitride semiconductor device, in the back surface electrode, a donor element concentration is preferably 1×10¹⁹ cm⁻³ or more in a depth range of at least 100 nm from the boundary surface between the back surface electrode and the semiconductor substrate. In this case, since the donor element concentration is increased not only in the semiconductor substrate but also in the back surface electrode, the contact resistance between the semiconductor substrate and the back surface electrode can be further reduced.

In the method for producing a nitride semiconductor device, in the semiconductor substrate formation step, the semiconductor substrate is preferably crystal-grown such that the donor element concentration is 1×10¹⁹ cm⁻³ or more and 1×10²² cm⁻³ or less in the semiconductor substrate in the depth range of at least 100 nm from the boundary surface between the semiconductor substrate and the back surface electrode. In this case, a decrease in crystallinity of the semiconductor substrate can be prevented, which can contribute to improving the performance of the nitride semiconductor device.

In the method for producing a nitride semiconductor device, the semiconductor substrate formation step is preferably performed by an OVPE method. In this case, when the semiconductor substrate is formed, the semiconductor substrate is easily crystal-grown such that oxygen (O) as the donor element is 1×10¹⁹ cm⁻³ or more, and reproducibility thereof is sufficiently high. In addition, since a conventional oxygen plasma treatment is not required, the semiconductor substrate is not damaged by the oxygen plasma treatment, and an increase in production cost can be prevented.

In the method for producing a nitride semiconductor device, the acid cleaning step and the back surface electrode formation step are preferably performed at an atmosphere temperature of 150° C. or lower. In this case, during the acid cleaning step and the back surface electrode formation step, the semiconductor layer and the front surface element formed on a front surface side of the semiconductor substrate can be prevented from being damaged by heat, and the performance of the nitride semiconductor device can be maintained.

In the method for producing a nitride semiconductor device, a heat treatment is preferably not performed in the back surface electrode formation step. In this case, the semiconductor layer and the front surface element formed on the front surface side of the semiconductor substrate can be prevented from being damaged by heat, and the performance of the nitride semiconductor device can be maintained.

### First Embodiment

### 1. Outline of Configuration of Nitride Semiconductor Device 1

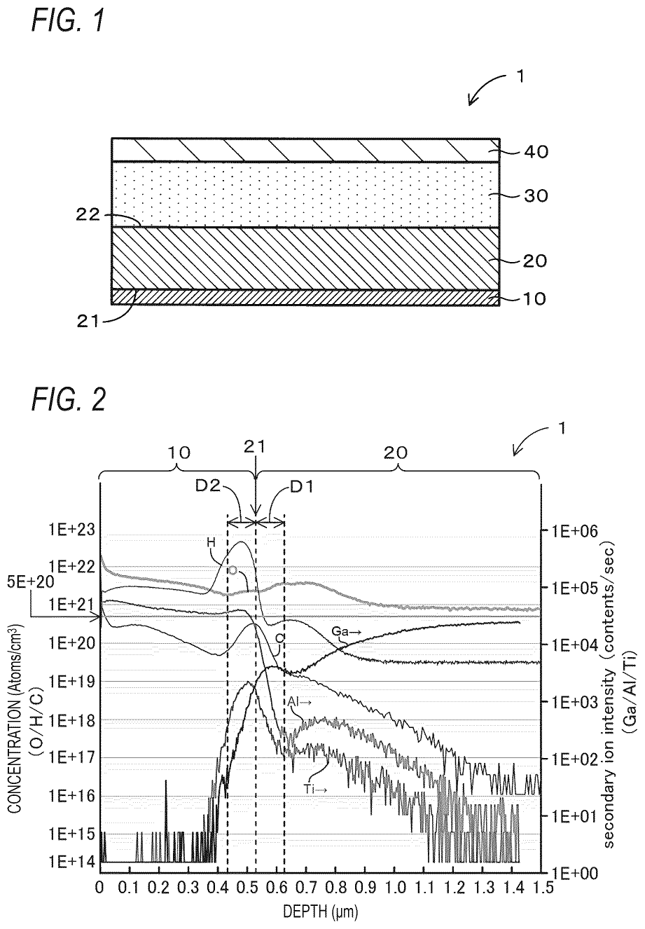

A configuration of a nitride semiconductor device 1 according to a first embodiment will be described below. As shown in FIG. 1, the nitride semiconductor device 1 according to the first embodiment has a structure in which a back surface electrode 10, a semiconductor substrate 20, a semiconductor layer 30, and a front surface element 40 are stacked in this order. Hereinafter, each configuration and forming method will be described in detail.

### 1-1. Semiconductor Substrate 20

The semiconductor substrate 20 is a substrate made of a Group III nitride semiconductor. In the present embodiment, a gallium nitride (GaN) substrate is used as the semiconductor substrate 20 and contains a donor element which is an impurity. The donor element can be, for example, any of oxygen (O), silicon (Si), and germanium (Ge). In the present embodiment, the semiconductor substrate 20 contains O as a donor element.

The back surface electrode 10 to be described later is stacked on a back surface side of the semiconductor substrate 20, and has a boundary surface 21 with the back surface electrode 10. The semiconductor substrate 20 has a donor element concentration of 1×10¹⁹ cm³ or more in a range of at least 100 nm from the boundary surface 21. FIG. 2 shows results of analyzing a depth position from a front surface of the back surface electrode 10 and contained elements in a structure in which the back surface electrode 10 to be described later is formed on the semiconductor substrate 20. Here, the boundary surface 21 is a depth position at which a detection intensity of Ga rapidly decreases, specifically, a depth position at which the detection intensity (4×10³) of Ga at a depth position (depth: 550 nm) before starting to decrease is 50%. In the present embodiment, as shown in FIG. 2, the semiconductor substrate 20 has a donor element concentration of 5×10²⁰ cm⁻³ in a range D1 of at least 100 nm from the boundary surface 21. Further, in the present embodiment, the semiconductor substrate 20 has a donor element concentration of 5×10²⁰ cm⁻³ throughout the entire semiconductor substrate 20, including a region deeper than 100 nm from the boundary surface 21 beyond the range D1. Note that, in FIG. 2, Ga is derived from GaN constituting the semiconductor substrate 20, and Ti and Al are derived from a metal constituting the back surface electrode 10.

A thickness of the semiconductor substrate 20 is not limited, and may be 1 μm or more, or 150 μm or more. The thickness of the semiconductor substrate is generally 300 μm to 400 μm, and the thickness of the semiconductor substrate 20 in the present embodiment is sufficiently thin. By sufficiently reducing the thickness of the semiconductor substrate 20, even in the case where a Schottky barrier is formed between the semiconductor substrate 20 and the back surface electrode 10, a barrier thickness can be sufficiently reduced, and the contact resistance between the semiconductor substrate 20 and the back surface electrode 10 can be reduced.

In the semiconductor substrate 20, in the case where the donor element concentration is more than 1×10²² cm⁻³, the crystallinity of the semiconductor substrate 20 may decrease, and thus the donor element concentration is preferably 1×10²² cm⁻³ or less. Accordingly, the crystallinity of the semiconductor substrate 20 can be prevented from decreasing, and the performance of the nitride semiconductor device 1 can be improved.

As described above, a method of forming the semiconductor substrate 20 is sufficiently a method capable of incorporating the donor element at a high concentration into the semiconductor substrate 20, and for example, an oxide vapor phase epitaxy (OVPE) method or an ammonothermal method can be used. Among them, it is preferable to use the OVPE method capable of incorporating O as a donor element at a high concentration into the semiconductor substrate 20.

In the OVPE method, a mixed gas obtained by mixing a Group III element-containing gas (for example, a Ga₂O gas) and a nitrogen element-containing gas (for example, a NH₃ gas, a NO gas, a NO₂ gas, a N₂H₂ gas, or a N₂H₄ gas) is injected toward a seed substrate made of GaN to react both gases, whereby crystal growth of a Group III nitride semiconductor can be performed on the seed substrate. Note that, in order to grow a Group III nitride semiconductor crystal, the temperature is preferably maintained at 1000° C. or higher and 1400° C. or lower. In the OVPE method, the donor element concentration (O) can be controlled by adjusting supply amounts of both gases.

After the semiconductor substrate 20 is formed, a back surface of the semiconductor substrate 20 to be the boundary surface 21 is preferably cleaned. A method of cleaning the semiconductor substrate 20 is not limited, and acid cleaning using hydrofluoric acid (HF), a dilute hydrofluoric acid (DHF) solution, or a buffered hydrofluoric acid (BHF) solution can be used as a chemical solution. A cleaning time is not limited, and may be 0.5 minutes or longer. By performing the acid cleaning, it is possible to remove organic substances or oxides unintentionally adhering to the back surface of the semiconductor substrate 20. Accordingly, the contact resistance between the semiconductor substrate 20 and the back surface electrode 10 can be reduced.

In the present embodiment, a carbon concentration in the back surface (boundary surface 21) of the semiconductor substrate 20 is less than 1×10²¹ cm⁻³, as shown in FIG. 2. More preferably, it is less than 5×10²⁰ cm⁻³. Accordingly, since the amount of carbon that causes an increase in contact resistance is small in the boundary surface 21, the contact resistance can be reduced.

In addition, in the present embodiment, a hydrogen concentration in the back surface (boundary surface 21) of the semiconductor substrate 20 is 1×10²¹ cm⁻³ or more, as shown in FIG. 2. Accordingly, since the boundary surface 21 is hydrogen-terminated, it is difficult to be oxidized, and it is possible to prevent the formation of an oxide on the back surface of the semiconductor substrate 20 after cleaning and to contribute to the reduction of the contact resistance.

### 1-2. Back Surface Electrode 10

The back surface electrode 10 is made of a metal and can be formed of an electrode material having a work function of 2.0 eV to 5.7 eV. As the electrode material, Ti, Al, Ni, Mg, Mo, V, Au, Ag, Cu, or the like can be used, and a compound such as TiN or AlCu may be used. Among them, it is preferable to contain any one or more of Au, Ag, and Cu. In the case of these electrode materials, a heat dissipation property of the nitride semiconductor device 1 can be improved. The back surface electrode 10 may be formed of a single layer or may be formed by stacking two or more layers.

The back surface electrode 10 may contain the donor element described above. The donor element concentration in the back surface electrode 10 may be 1×10¹⁹ cm⁻³ or more in a range of at least 100 nm from the boundary surface 21 between the back surface electrode 10 and the semiconductor substrate 20. A donor element contained in the back surface electrode 10 may be the donor element contained in the semiconductor substrate 20 leaking from the semiconductor substrate 20 in the process of forming the back surface electrode 10. When the back surface electrode 10 contains the above donor element, the work function of the back surface electrode 10 can be further reduced, and the contact resistance between the semiconductor substrate 20 and the back surface electrode 10 can be reduced.

A method of forming the back surface electrode 10 is not limited, and a sputtering method, an electron beam evaporation method, or a specific resistance heating method can be used. In the present embodiment, the back surface electrode 10 is formed by introducing an inert gas such as Ar or N into a vacuum environment by a sputtering method. Note that, a heat treatment for alloying is not required after the formation of the back surface electrode 10. The back surface electrode 10 can be formed at an environmental temperature of lower than 450° C., and preferably 150° C. or lower. Accordingly, it is possible to prevent performance deterioration of the semiconductor layer 30 to be described later.

### 1-3. Contact Resistance

The contact resistance at the boundary surface 21 between the back surface electrode 10 and the semiconductor substrate 20 can be 1×10⁻⁵ Ωcm² or less, and more preferably 2×10⁻⁶ Ωcm² or less by the semiconductor substrate 20 and the back surface electrode 10 having the above configuration.

### 1-4. Semiconductor Layer 30 and Front Surface Element 40

The semiconductor layer 30 is formed on an upper surface 22 of the semiconductor substrate 20. A configuration of the semiconductor layer 30 is not limited and may be a desired semiconductor layer. In the present embodiment, a Group III nitride semiconductor layer is formed. The front surface element 40 is formed on the semiconductor layer 30. A configuration of the front surface element 40 is not limited, and includes an electrode.

A method of forming the semiconductor layer 30 and the front surface element 40 is also not limited, and the semiconductor layer 30 and the front surface element 40 can be formed by a desired method. The semiconductor layer 30 and the front surface element 40 are formed after the semiconductor substrate 20 is formed and before the back surface electrode 10 is formed. After the semiconductor layer 30 and the front surface element 40 are formed, the back surface of the semiconductor substrate 20 can be cleaned.

### 2. Method for Producing Nitride Semiconductor Device 1

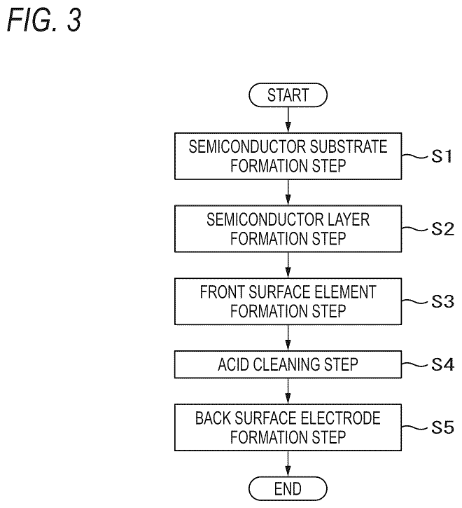

Next, a method for producing the nitride semiconductor device 1 according to the present embodiment will be described with reference to a flowchart shown in FIG. 3. The method for producing the nitride semiconductor device 1 according to the present embodiment includes a semiconductor substrate formation step S1, a semiconductor layer formation step S2, a front surface element formation step S3, an acid cleaning step S4, and a back surface electrode formation step S5.

First, in the semiconductor substrate formation step S1, the above semiconductor substrate 20 is formed. In the present embodiment, the semiconductor substrate 20 is formed by the OVPE method as described above. Accordingly, the semiconductor substrate 20 is formed to contain O as a donor element at a high concentration.

Next, in the semiconductor layer formation step S2, the semiconductor layer 30 is formed on the upper surface 22 of the semiconductor substrate 20, and thereafter, in the front surface element formation step S3, the front surface element 40 is formed on the semiconductor layer 30. Then, in the acid cleaning step S4, the back surface 21 of the semiconductor substrate 20 is acid-cleaned. In the present embodiment, the acid cleaning is performed at room temperature.

Thereafter, in the back surface electrode formation step S5, the back surface electrode 10 is formed on the upper surface 22 of the semiconductor substrate 20. In the present embodiment, the back surface electrode 10 is formed by a sputtering method. In the present embodiment, the back surface electrode formation step S5 is performed at room temperature. After the back surface electrode formation step S5 is performed, the flow is ended.

### 3. Operations and Effects

In the nitride semiconductor device 1 according to the present embodiment, since, in the semiconductor substrate 20, the donor element concentration is 1×10¹⁹ cm⁻³ or more in the depth range D1 of at least 100 nm from the boundary surface 21 between the semiconductor substrate 20 and the back surface electrode 10, a region where the donor element concentration is a high concentration in the semiconductor substrate 20 is present up to a sufficiently deep position from the boundary surface 21. Accordingly, the effect of reducing the contact resistance between the semiconductor substrate 20 and the back surface electrode 10 can be sufficiently obtained. As a result, the nitride semiconductor device 1 having an increased current can be obtained without performing a high-temperature heat treatment.

In the present embodiment, the donor element concentration is 1×10¹⁹ cm⁻³ or more and 1×10²² cm⁻³ or less in the semiconductor substrate 20 in the depth range of at least 100 nm from the boundary surface 21 between the semiconductor substrate 20 and the back surface electrode 10. Accordingly, a decrease in crystallinity of the semiconductor substrate 20 can be prevented, which can contribute to improving the performance of the nitride semiconductor device 1.

In the present embodiment, the contact resistance between the semiconductor substrate 20 and the back surface electrode 10 is 1×10⁻⁵ Ωcm² or less, and further 2×10⁻⁶ Ωcm² or less. Accordingly, since the contact resistance between the semiconductor substrate 20 and the back surface electrode 10 is sufficiently reduced, it is possible to meet the demand for increasing a current.

In the present embodiment, the donor element in the semiconductor substrate 20 is O. Accordingly, the donor element concentration in the semiconductor substrate 20 can be easily increased.

In the present embodiment, the donor element concentration is 1×10¹⁹ cm⁻³ or more in the back surface electrode 10 in a depth range D2 of at least 100 nm from the boundary surface 21 between the semiconductor substrate 20 and the back surface electrode 10. Accordingly, since the donor element concentration is increased not only in the semiconductor substrate 20 but also in the back surface electrode 10, the contact resistance between the semiconductor substrate 20 and the back surface electrode 10 can be further reduced.

In the present embodiment, the method for producing the nitride semiconductor device 1 includes the semiconductor substrate formation step S1, the semiconductor layer formation step S2, the front surface element formation step S3, the acid cleaning step S4, and the back surface electrode formation step S5 described above, and the semiconductor substrate is crystal-grown such that the donor element concentration is 1×10¹⁹ cm⁻³ or more in the semiconductor substrate 20 in the depth range of at least 100 nm from the boundary surface 21 between the semiconductor substrate 20 and the back surface electrode 10. Accordingly, since the region where the donor element concentration 20 is a high concentration in the semiconductor substrate is present up to a sufficiently deep position from the boundary surface 21, the effect of reducing the contact resistance between the semiconductor substrate 20 and the back surface electrode 10 can be sufficiently obtained. As a result, the nitride semiconductor device 1 having an increased current can be obtained without performing a high-temperature heat treatment.

In the present embodiment, in the semiconductor substrate formation step S1, the semiconductor substrate 20 is crystal-grown such that the donor element concentration is 1×10¹⁹ cm⁻³ or more and 1×10²² cm⁻³ or less in the semiconductor substrate 20 in the depth range of at least 100 nm from the boundary surface 21 between the semiconductor substrate 20 and the back surface electrode 10. Accordingly, a decrease in crystallinity of the semiconductor substrate 20 can be prevented, which can contribute to improving the performance of the nitride semiconductor device 1.

In the present embodiment, in the method for producing the nitride semiconductor device 1, in the semiconductor substrate formation step SI is performed by an OVPE method. Accordingly, when the semiconductor substrate 20 is formed, the semiconductor substrate 20 is easily crystal-grown such that oxygen (O) as the donor element is 1×10¹⁹ cm⁻³ or more, and the reproducibility thereof is sufficiently high. In addition, since a conventional oxygen plasma treatment is not required, the semiconductor substrate 20 is not damaged by the oxygen plasma treatment, and an increase in production cost can be prevented.

In the present embodiment, the acid cleaning step S4 and the back surface electrode formation step S5 are performed at an atmosphere temperature of 150° C. or lower. Accordingly, during the acid cleaning step S4 and the back surface electrode formation step S5, the semiconductor layer 30 and the front surface element 40 formed on the front surface (upper surface 22) side of the semiconductor substrate 20 can be prevented from being damaged by heat, and the performance of the nitride semiconductor device 1 can be maintained.

In the present embodiment, a heat treatment is not performed in the back surface electrode formation step S5. Accordingly, the semiconductor layer 30 and the front surface element 40 formed on the front surface (upper surface 22) side of the semiconductor substrate 20 can be prevented from being damaged by heat, and the performance of the nitride semiconductor device 1 can be maintained.

As described above, according to the present embodiment, it is possible to provide the nitride semiconductor device 1 capable of reducing the contact resistance between the semiconductor substrate 20 and the back surface electrode 10 without performing a high-temperature heat treatment to meet the demand for increasing a current.

The present invention is not limited to the above-described embodiments, and may be applied to various embodiments without departing from the gist of the present invention.

### REFERENCE SIGNS LIST

1 nitride semiconductor device
10 back surface electrode
20 semiconductor substrate
21 boundary surface (back surface)
22 upper surface (front surface)
30 semiconductor layer
40 front surface element

What is claimed is:

1. A nitride semiconductor device comprising:
a back surface electrode;
a semiconductor substrate;
a semiconductor layer; and
a front surface element, stacked in this order, wherein
in the semiconductor substrate, a concentration of a donor element is 1×10¹⁹ cm⁻³ or more in a depth range of at least 100 nm from a boundary surface between the semiconductor substrate and the back surface electrode.

2. The nitride semiconductor device according to claim 1, wherein in the semiconductor substrate, the concentration of the donor element is 1×10¹⁹ cm⁻³ or more and 1×10²² cm⁻³ or less in the depth range of at least 100 nm from the boundary surface between the semiconductor substrate and the back surface electrode.

3. The nitride semiconductor device according to claim 1, wherein a contact resistance between the semiconductor substrate and the back surface electrode is1×10⁻⁵ Ωcm² or less.

4. The nitride semiconductor device according to claim 2, wherein a contact resistance between the semiconductor substrate and the back surface electrode is 1×10⁻⁵ Ωcm² or less.

5. The nitride semiconductor device according to claim 1, wherein a contact resistance between the semiconductor substrate and the back surface electrode is 2×10⁻⁶ Ωcm² or less.

6. The nitride semiconductor device according to claim 2, wherein a contact resistance between the semiconductor substrate and the back surface electrode is 2×10⁻⁶ Ωcm² or less.

7. The nitride semiconductor device according to claim 1, wherein the donor element in the semiconductor substrate is at least one of O, Si or Ge.

8. The nitride semiconductor device according to claim 2, wherein the donor element in the semiconductor substrate is at least one of O, Si or Ge.

9. The nitride semiconductor device according to claim 1, wherein in the back surface electrode, a concentration of a donor element is 1×10¹⁹ cm⁻³ or more in a depth range of at least 100 nm from the boundary surface between the back surface electrode and the semiconductor substrate.

10. The nitride semiconductor device according to claim 2, wherein in the back surface electrode, a concentration of a donor element is 1×10¹⁹ cm⁻³ or more in a depth range of at least 100 nm from the boundary surface between the back surface electrode and the semiconductor substrate.

11. A method for producing a nitride semiconductor device in which a back surface electrode, a semiconductor substrate, a semiconductor layer, and a front surface element are stacked in this order, the method comprising:
crystal-growing the semiconductor substrate such that a concentration of a donor element is 1×10¹⁹ cm⁻³ or more in the semiconductor substrate in a depth range of at least 100 nm from a boundary surface between the semiconductor substrate and the back surface electrode;
forming the semiconductor layer on one surface of the semiconductor substrate;
forming the front surface element on the semiconductor layer;
acid-cleaning a surface of the semiconductor substrate opposite to a side on which the semiconductor layer is formed; and
forming the back surface electrode on the surface of the semiconductor substrate opposite to the side on which the semiconductor layer is formed.

12. The method for producing a nitride semiconductor device according to claim 11, wherein in the crystal-growing of the semiconductor substrate, the semiconductor substrate is crystal-grown such that the concentration of the donor element is 1×10¹⁹ cm⁻³ or more and 1×10²² cm⁻³ or less in the semiconductor substrate in the depth range of at least 100 nm from the boundary surface between the semiconductor substrate and the back surface electrode.

13. The method for producing a nitride semiconductor device according to claim 11, wherein the crystal-growing of the semiconductor substrate is performed by an OVPE method.

14. The method for producing a nitride semiconductor device according to claim 12, wherein the crystal-growing of the semiconductor substrate is performed by an OVPE method.

15. The method for producing a nitride semiconductor device according to claim 11, wherein the acid-cleaning and the forming of the back surface electrode are performed at an atmosphere temperature of 150° C. or lower.

16. The method for producing a nitride semiconductor device according to claim 12, wherein the acid-cleaning and the forming of the back surface electrode are performed at an atmosphere temperature of 150° C. or lower.

17. The method for producing a nitride semiconductor device according to claim 11, wherein a heat treatment is not performed in the forming of the back surface electrode.

18. The method for producing a nitride semiconductor device according to claim 12, wherein a heat treatment is not performed in the forming of the back surface electrode.
